(19) United States
(12) Patent Application Publication
(10) Pub. No.: US 2011/0138211 A1
(43) Pub. Date: Jun. 9, 2011

(54) APPARATUS AND METHOD FOR USING MULTIPLE MEMORIES IN A PORTABLE TERMINAL

(75) Inventor: Young-Seok KIM, Seoul (KR)

(73) Assignee: SAMSUNG ELECTRONICS CO. LTD., Suwon-si (KR)

(21) Appl. No.: 12/963,080

(22) Filed: Dec. 8, 2010

(30) Foreign Application Priority Data
Dec. 9, 2009 (KR) 10-2009-0122042

(51) Int. Cl. G06F 1/32; G11C 5/14

(52) U.S. Cl. 713/324; 365/226; 365/227

(57) ABSTRACT

An apparatus and method for using a plurality of memories in a portable terminal are provided. The method includes detecting insertion of a first memory card, determining whether a second memory card is inserted, and controlling power for the first memory card according to whether the second memory card is inserted.

### PRIORITY

This application claims the benefit under 35 U.S.C. §119(a) of a Korean patent application filed in the Korean Intellectual Property Office on Dec. 9, 2009 and assigned Serial No. 10-2009-0122042, the entire disclosure of which is hereby incorporated by reference.

### BACKGROUND OF THE INVENTION

1. Field of the Invention

The present invention relates to a portable terminal. More particularly, the present invention relates to an apparatus and a method for using a plurality of memories in the portable terminal.

2. Description of the Related Art

Recently, a portable terminal for processing digital data has been developed that supports additional attachable/detachable memory cards to satisfy users' demands of storing more data. That is, the portable terminal employs a socket capable of detecting an additional memory card, so that when the memory card is inserted into the socket, the portable terminal accesses the inserted memory card to perform a certain operation, e.g., an operation of outputting the stored data or an operation of storing specific data, and the like. The portable terminal supporting the additional memory card may be a personal portable terminal, a digital camera, a mobile communication terminal, and the like. The memory card may be a T-flash memory card, a Secure Digital (SD) card, a micro SD card, and the like.

FIG. 1 is a block diagram illustrating a structure of a portable terminal according to the related art.

Referring to FIG. 1, the portable terminal allows a Central Processing Unit (CPU) 100 to detect and control only one memory card 110. That is, when the memory card 110 is inserted into the portable terminal, the CPU 100 detects insertion of the memory card 110 through a port INT, and controls a Low Drop Out (LDO) regulator 120 through a port General Purpose Input/Output (GPIO) to supply power to the memory card 110. Thereafter, the CPU 100 processes data by accessing the memory card 110 through a port Secure Digital Input/Output (SDIO).

As described above, the portable terminal of the related art has a socket capable of detecting one memory card, and thus supports only one memory card at once. Therefore, if a user has two or more memory cards, the user has to detach a memory card inserted into the portable terminal and then insert a second card whenever the user desires to use the second memory card, which leads to inconvenience of the user. In addition, there is a great possibility of losing a memory card not inserted into the portable terminal.

### SUMMARY OF THE INVENTION

An aspect of the present invention is to address at least the above-mentioned problems and/or disadvantages and to provide at least the advantages described below. Accordingly, an aspect of the present invention is to provide an apparatus and a method for using a plurality of memories in a portable terminal.

Another aspect of the present invention is to provide an apparatus and a method for supporting a plurality of memories by employing a plurality of sockets for memory detection in a portable terminal.

Another aspect of the present invention is to provide an apparatus and a method for controlling power for each memory based on whether the memory is in use when a plurality of memories are inserted in a portable terminal.

In accordance with an aspect of the present invention, a method for using a plurality of memories in a portable terminal is provided. The method includes detecting insertion of a first memory card, determining whether a second memory card is inserted, and controlling power for the first memory card according to whether the second memory card is inserted.

In accordance with another aspect of the present invention, an apparatus for using a plurality of memories in a portable terminal is provided. The apparatus includes a Central Processing Unit (CPU) for detecting whether a plurality of memory cards are inserted, and upon detecting insertion of a first memory card among the plurality of memory cards, for controlling power for the first memory card according to whether a second memory card is inserted, and a plurality of power supply units for turning on/off power for corresponding memory cards under the control of the CPU.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a block diagram illustrating a structure of a portable terminal according to the related art;

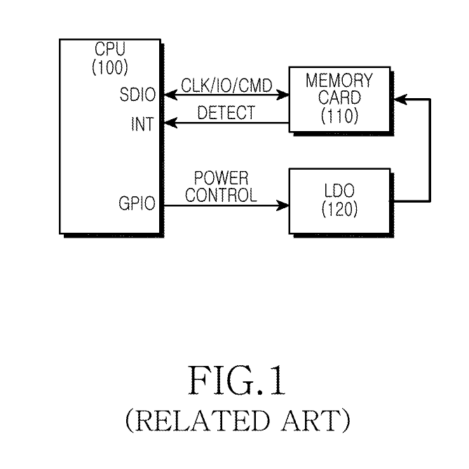

FIG. 2 is a block diagram illustrating a structure of a portable terminal according to an exemplary embodiment of the present invention; and

FIG. 3 is a flowchart illustrating a process of supporting a plurality of memory cards in a portable terminal according to an exemplary embodiment of the present invention.

Throughout the drawings, it should be noted that like reference numbers are used to depict the same or similar elements, features, and structures

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Exemplary embodiments of the present invention provide a method for supporting a plurality of memories in a portable terminal. Although a case where the portable terminal supports two memory cards will be described, for example, in the following description, the present invention may also equally apply to a case where two or more memory cards are supported. In addition, the memory card includes all types of memory cards that may be inserted into the portable terminal, such as, a T-flash memory card, a Secure Digital (SD) card, a micro SD card, and the like.

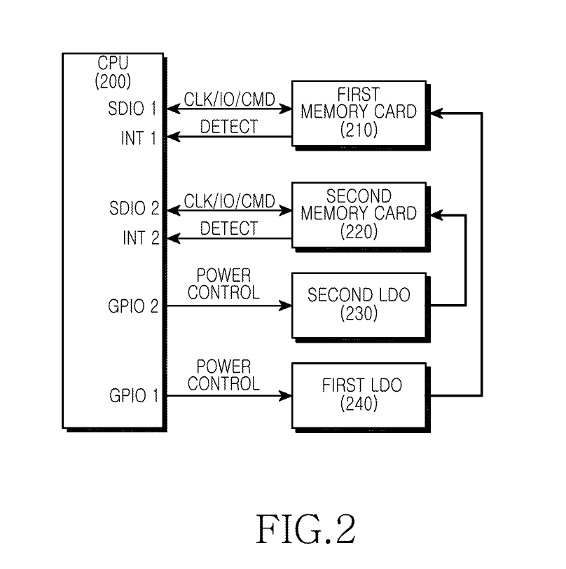

FIG. 2 is a block diagram illustrating a structure of a portable terminal according to an exemplary embodiment of the present invention.

Referring to FIG. 2, the portable terminal includes a Central Processing Unit (CPU) 200, a second Low Drop Out (LDO) regulator (hereinafter, referred to as LDO) 230, and a first LDO 240. A first memory card 210 and a second memory card 220 may be inserted into the portable terminal.

The CPU 200 controls and processes overall operations of the portable terminal. In an exemplary embodiment of the present invention, the CPU 200 detects insertion of each of the first memory card 210 and the second memory card 220. When the first memory card 210 and the second memory card 220 are both inserted, the CPU 200 controls power on/off for a last inserted memory card according to whether a first inserted memory card is in use between the first memory card 210 and the second memory card 220.

More specifically, the CPU 200 detects insertion of the first memory card 210 according to a phase change of a port INT1, and detects insertion of the second memory card 220 according to a phase change of a port INT2. Upon detecting insertion of the first memory card 210 through the port INT1, the CPU 200 determines whether to supply power to the first memory card 210 according to whether the second memory card 220 is inserted and in use. Further, by outputting a control signal for indicating whether to supply the power through a port GPIO1, the CPU 200 controls on/off for the first memory card 210. In addition, upon detecting insertion of the second memory card 220 through the port INT2, the CPU 200 determines whether to supply power to the second memory card 220 according to whether the first memory card 210 is inserted and in use. Further, by outputting a control signal for indicating whether to supply the power through a port GPIO2, the CPU 200 controls on/off for the second memory card 220. Herein, an interface between the CPU 200 and the first memory card 210 and the second memory card 220 is configured with an additional SD block.

Upon detecting insertion of the first memory card 210, the CPU 200 evaluates whether the second memory card 220 is in a state of being inserted into the portable terminal. In this case, if the second memory card 220 is not in the state of being inserted into the portable terminal, the CPU 200 determines to supply power to the second memory card 220 and thereafter outputs a control signal for indicating the determination result to the first LDO 240 through the port GPIO1. Accordingly, the CPU 200 supplies power to the first memory card 210 and accesses the first memory card 210 through a port SDIO1. Otherwise, if the second memory card 220 is in the state of being inserted into the portable terminal, the CPU 200 determines whether to supply power to the first memory card 210 according to whether the first inserted second memory card 220 is in use. Herein, whether the second memory card 220 is in use may be determined according to whether an operation is performed using data stored in the second memory card 220 or whether data is being stored in the second memory card 220. If the second memory card 220 is currently in use, the CPU 200 determines not to supply power to the first memory card 210, and outputs a control signal for indicating the determination result to the first LDO 240 through the port GPIO1. Otherwise, if the second memory card 220 is not currently in use, the CPU 200 determines to supply power to the first memory card 210, outputs a control signal for indicating the determination result to the first LDO 240 through the port GPIO1, and then accesses the first memory card 210. Such an operation is equally applied even if the second memory card 220 is inserted.

In addition, in a state where the two memory cards 210 and 220 are inserted in such a manner that power is supplied to the first memory card 210 and power is not supplied to the second memory card 220, if an event for requiring access to the second memory card 220 occurs, the CPU 200 stops the supply of power to the first memory card 210 and outputs control signals for enabling the supply of power to the second memory card 220 through the ports GPIO1 and GPIO2. Thus, the CPU 200 may access the second memory card 220.

The first memory card 210 and the second memory card 220 are memory cards that may be attached to and detached from the portable terminal. The first memory card 210 and the second memory card 220 receive power by means of the second LDO 230 and the first LDO 240, receive a clock through the ports SDIO1 and SDIO2 of the CPU 200, perform data input/output, and transmit and receive a command signal for data processing. The first memory card 210 and the second memory card 220 may be T-flash memory cards, SD cards, micro SD cards and the like.

The second LDO 230 and the first LDO 240 supply power to a corresponding memory card or stop the supply of power according to a control signal output from the CPU 200.

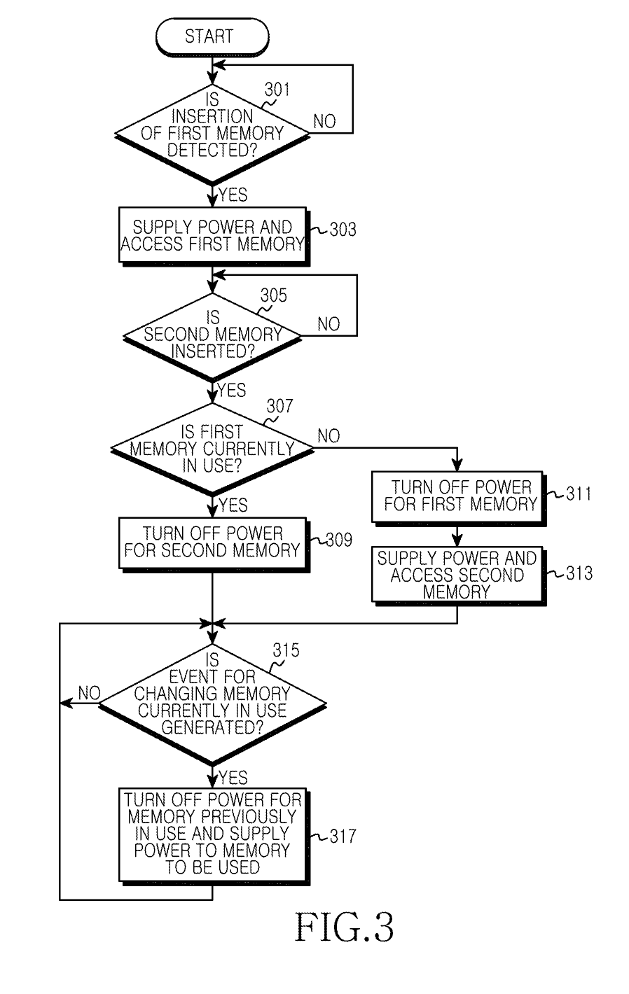

FIG. 3 is a flowchart illustrating a process of supporting a plurality of memory cards in a portable terminal according to an exemplary embodiment of the present invention.

Although it is assumed herein that the first memory card 210 is first inserted and then the second memory card 220 is inserted, it should be understood that the memory cards 210 and 220 order of insertion is for exemplary purposes only. Thus, the memory cards 210 and 220 may be inserted in any order.

Referring to FIG. 3, the portable terminal detects insertion of a first memory card 210 in step 301. The insertion of the first memory card 210 may be detected according to a phase change of port INT1 of the CPU 200.

Upon detecting insertion of the first memory card 210, the portable terminal supplies power and accesses the first memory card 210 in step 303. In this case, the portable terminal may output a power on/off signal to the port GPIO1 of the CPU 200 to supply power to the first memory card 210 by controlling the first LDO 240.

In step 305, the portable terminal detects insertion of the second memory card 220. If the second memory card 220 is inserted in step 305, the portable terminal determines whether the first memory card 210 inserted is currently in use in step 307. For example, the portable terminal determines whether data stored in the first memory card 210 is in use or data is being stored in the first memory card 210.

If it is determined that the first memory card 210 is in use in step 307, the portable terminal turns off power for the second memory card 220 in step 309. The procedure then proceeds to step 315. In this case, the portable terminal maintains a power-on state for the first memory card 210.

Otherwise, if it is determined that the first memory card 210 is not in use, the portable terminal turns off power for the first memory card 210 in step 311. In step 313, the portable terminal supplies power and accesses the second memory card 220. Then, the procedure proceeds to step 315.

In step 315, the portable terminal determines whether an event for changing a memory currently in use is generated under the control of a user. If it is determined that the event for changing the memory currently in use is generated in step 315, the portable terminal turns off power for the memory card previously in use, applies power to a memory card to be used in step 317. The procedure then returns to step 315 and the subsequent steps are repeated. For example, in a state where power of the first memory card 210 is on and power of the second memory card 220 is off, when an event for storing data in the second memory card 220 is generated, the portable terminal turns off power of the first memory card 210, supplies power to the second memory card 220, and accesses the second memory card 220.

As described above, when the event for changing the memory currently in use is generated under the control of the user, the power of the memory card previously in use is off and the power of the memory card to be used is on. However, even if the event for changing the memory currently in use is not generated, the power of the memory card previously in use may be off if the memory card previously in use is not used for a specific time period or if the use of the memory card ends. For example, when two memory cards are not used in a state where the two memory cards are inserted into the portable terminal, power for the two memory cards may be off.

According to exemplary embodiments of the present invention, a portable terminal employs a plurality of sockets for memory detection to enable insertion of a plurality of memories, and controls power for each memory based on whether the plurality of memories are used. Therefore, memory cards are effectively used while avoiding collision of the memory cards, and data is transferred between the memory cards without an external setting. Further, data transfer time is decreased and power consumption is reduced between the portable terminal has the same effect as a case of supporting one memory card.

While the invention has been shown and described with reference to certain exemplary embodiments thereof, it will be understood by those skilled in the art that various changes in form and details may be made therein without departing from the spirit and scope of the present invention as defined by the appended claims and their equivalents.

What is claimed is:

1. A method for using a plurality of memories in a portable terminal, the method comprising:
detecting insertion of a first memory card;
determining whether a second memory card is inserted; and
controlling power for the first memory card according to whether the second memory card is inserted.

2. The method of claim 1, wherein the controlling of the power for the first memory card comprises:
if the second memory card is inserted, determining whether the second memory card is in use; and
if the second memory card is in use, turning off the power for the first memory card, and if the second memory card is not in use, turning on the power for the first memory card.

3. The method of claim 2, further comprising:
if the second memory card is not in use, turning off the power for the second memory card.

4. The method of claim 2, further comprising:
if the second memory card is not inserted, turning on the power for the first memory card.

5. The method of claim 2, further comprising:
if an event for changing the memory in use is generated in a state where the power for the first memory card is off, turning on the power for the first memory card and turning off the power for the second memory card.

6. The method of claim 2, further comprising:
if an event for storing data in a second memory card is generated in a state where power for the first memory card is on, turning off the power for the first memory card and turning on the power to the second memory card.

7. The method of claim 2, wherein the first memory card and the second memory card each comprise an interface that is configured with a separate Secure Digital (SD) block in the portable terminal.

8. An apparatus for using a plurality of memories in a portable terminal, the apparatus comprising:
a Central Processing Unit (CPU) for detecting whether a plurality of memory cards are inserted, and upon detecting insertion of a first memory card among the plurality of memory cards, for controlling power for the first memory card according to whether a second memory card is inserted; and
a plurality of power supply units for turning on/off power for corresponding memory cards under the control of the CPU.

9. The apparatus of claim 8, wherein the CPU determines whether the second memory card is in use if the second memory card is inserted, turns off the power for the first memory card if the second memory card is in use, and turns on the power for the first memory card if the second memory card is not in use.

10. The apparatus of claim 9, wherein, if the second memory card is not in use, the CPU turns off the power for the second memory card.

11. The apparatus of claim 9, wherein, if the second memory card is not inserted, the CPU turns on the power for the first memory card.

12. The apparatus of claim 9, wherein, if an event for changing the memory in use is generated in a state where the power for the first memory card is off, the CPU turns on the power for the first memory card and turns off the power for the second memory card.

13. The apparatus of claim 9, wherein, if an event for storing data in a second memory card is generated in a state where power for the first memory card is on, the CPU turns off the power for the first memory card and turning on the power for the second memory card.

14. The apparatus of claim 9, wherein the CPU and each of the plurality of memory cards comprise an interface that is configured with a separate Secure Digital (SD) block.
